(19) United States
(12) Patent Application Publication
(10) Pub. No.: US 2008/0176402 A1
(43) Pub. Date: Jul. 24, 2008

(54) METHOD FOR FABRICATING SEMICONDUCTOR DEVICE WITH RECESS GATE

(75) Inventors: Myung-Ok KIM, Ichon-shi (KR); Tae-Woo JUNG, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/968,446

(22) Filed: Jan. 2, 2008

(30) Foreign Application Priority Data
Jan. 4, 2007 (KR) 10-2007-0000999

(51) Int. Cl. H01L 21/311

(52) U.S. Cl. 438/694; 257/E21.249

(57) ABSTRACT

A method for fabricating a semiconductor device includes providing a substrate, forming a sacrificial oxide layer over the substrate, the sacrificial layer having a higher etch rate than the substrate, forming a hard mask pattern over the sacrificial oxide layer, wet-etching the sacrificial oxide layer using the hard mask pattern as an etch barrier, and forming a recess by etching an exposed substrate using the hard mask pattern as an etch barrier.

### CROSS-REFERENCE TO RELATED APPLICATIONS

The present invention claims priority of Korean patent application number 2007-0000999, filed on Jan. 4, 2007, which is incorporated by reference in its entirety.

### BACKGROUND OF THE INVENTION

The present invention relates to a method for fabricating a semiconductor device, and more particularly, to a method for fabricating a semiconductor device with a recess gate.

At present, since, semiconductor devices have become highly integrated, a process for forming a recess gate has been introduced to improve its refresh characteristics. The process for forming the recess gate includes etching a portion of an active region in a substrate, thereby forming a recess, and then forming a gate over the recess so as to increase a channel length of a cell transistor.

Further, in the process for forming the recess gate, a field oxide layer is formed to define the active region in the substrate. Then, a sacrificial oxide layer and a hard mask layer, functioning as an etch barrier in a subsequent etch process, are formed over the substrate including the field oxide layer. A photoresist pattern is formed over the hard mask layer to define a recess target region.

Further, the hard mask layer and the sacrificial oxide layer are sequentially etched using the photoresist pattern as a mask. Specifically, the hard mask layer is etched by using the photoresist pattern as a mask thereby exposing the sacrificial oxide layer. While etching the hard mask layer, a portion of the sacrificial oxide layer may be lost. The sacrificial oxide layer is etched using the etched hard mask layer as an etch barrier to expose the substrate. Further, while etching the sacrificial oxide layer, a portion of the substrate may be lost. Generally, etching the hard mask layer and the sacrificial oxide layer is accomplished by an anisotropic dry-etch process.

Subsequently, the substrate is etched using the etched hard mask layer and the etched sacrificial oxide layer as an etch barrier to form the recess. Thus, the recess gate is formed. A portion of the gate fills the recess and the remaining portion protrudes from a surface of the substrate.

However, to improve the refresh characteristic of the device, during the process for forming the recess gate, several conditions are to be met. For instance, uniformity of a recess depth should be maintained, a loss of the field oxide layer should be minimized, and a top corner of the recess should have a round shape. However, since a typical process for forming the recess gate does not satisfy the above-mentioned conditions, the refresh characteristic of the device is deteriorated.

FIG. 1 is a micrographic view illustrating non-uniformity in recess depth when a typical process for forming a recess gate is employed.

Referring to FIG. 1, a depth of a right recess pattern (A) is deeper than that of a left recess pattern. This result is obtained because the loss of the sacrificial oxide layer during etching the hard mask layer or the loss of the substrate during etching the sacrificial oxide layer is not constant. Further, it is also difficult to adjust or control the loss using the anisotropic etch process. Thus, in a subsequent etch process for forming the recess, it is difficult to keep the depth of the recess constant.

FIG. 2 is a micrographic view illustrating a field oxide layer overly etched during a typical process for forming a recess gate.

Referring to FIG. 2, the amount of field oxide layer lost is high (B). This is because, when the sacrificial oxide layer is anisotropically dry-etched, the field oxide layer, including the same material as that used to form the sacrificial oxide layer, is simultaneously etched. Further, when the field oxide layer is overly etched, a voltage coupling occurs between the neighboring gates. Thus a leaking current due to a threshold voltage drop increases, thereby resulting in the deterioration of the refresh characteristic.

FIG. 3 is a micrographic view illustrating a beak generated in a top corner of the recess.

Referring to FIG. 3, the beak (C) is generated in the top corner of the recess (refer to ‘C’). The beak functions as a source of the leaking current since an electric field is concentrated on the top corner of the recess during an operation of a transistor.

Therefore, to obviate the above-mentioned drawbacks, a technique is required for securing the uniformity of the recess depth, minimizing a loss of the field oxide layer, and thus preventing generation of the beak in the top corner of the recess.

### SUMMARY OF THE INVENTION

Embodiments of the present invention are directed to provide a method for fabricating a semiconductor device with a recess gate.

In accordance with an aspect of the present invention, there is provided a method for fabricating a semiconductor device. The method includes providing a substrate, forming a sacrificial oxide layer over the substrate, the sacrificial layer having a higher etch rate than the substrate, forming a hard mask pattern over the sacrificial oxide layer, wet-etching the sacrificial oxide layer using the hard mask pattern as an etch barrier, and forming a recess by etching an exposed substrate using the hard mask pattern as an etch barrier.

### BRIEF DESCRIPTION OF THE DRAWINGS

FIG. 1 is a micrographic view illustrating non-uniformity in recess depth when a typical process of forming a recess gate is employed.

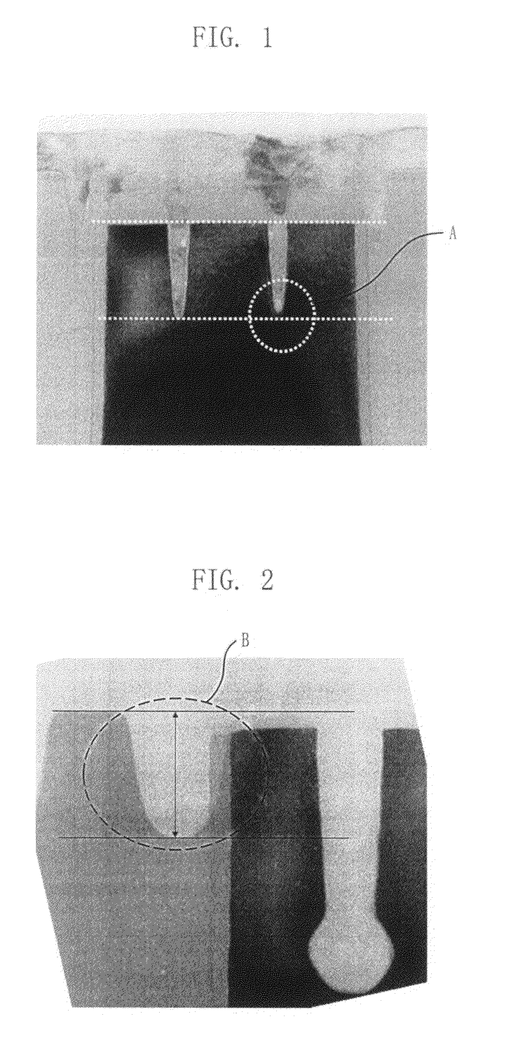

FIG. 2 is a micrographic view illustrating a field oxide layer overly etched during a typical process for forming a recess gate.

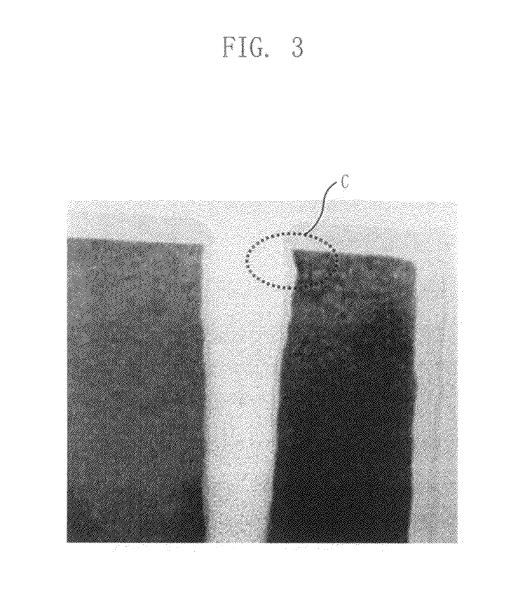

FIG. 3 is a micrographic view illustrating a beak generated on a top corner of the recess.

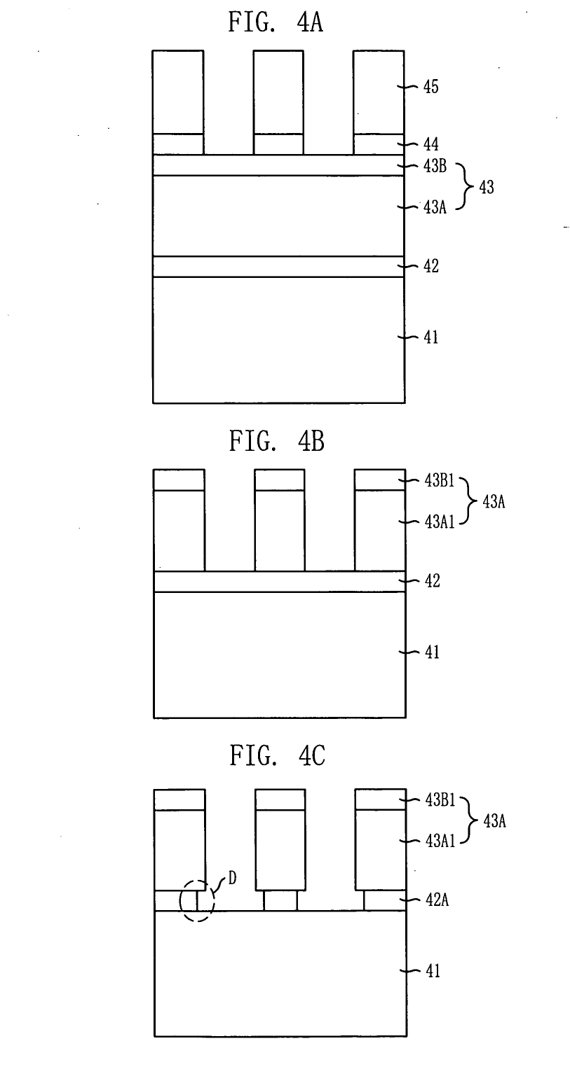

FIGS. 4A to 4F are cross-sectional views of a method for fabricating a semiconductor device with a recess gate in accordance with an embodiment of the present invention.

### DESCRIPTION OF SPECIFIC EMBODIMENTS

Embodiments of the present invention relate to a method for fabricating a semiconductor device with a recess gate.

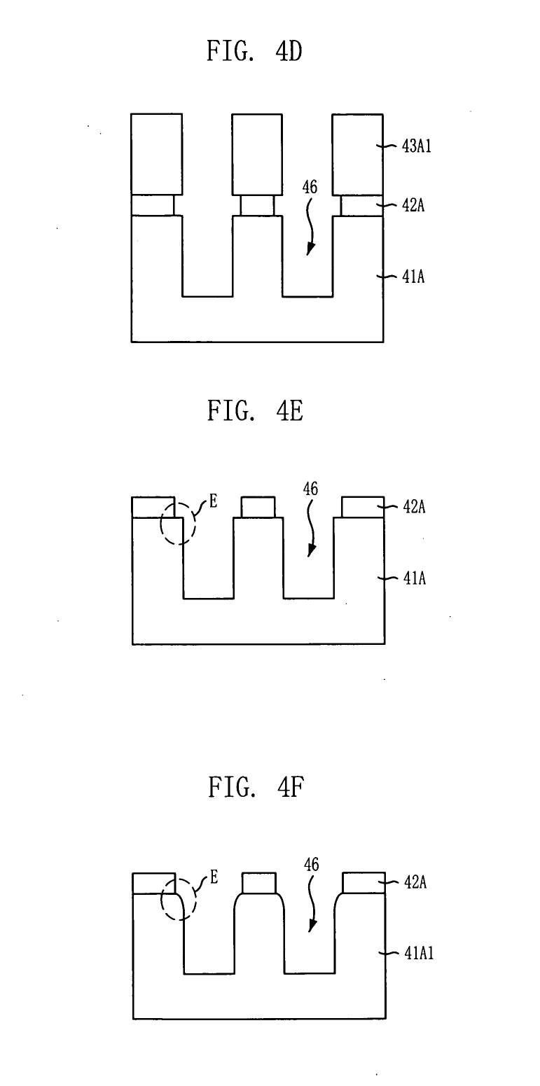

FIGS. 4A to 4F are cross-sectional views of a method for fabricating a semiconductor device with a recess gate in accordance with an embodiment of the present invention.

Referring to FIG. 4A, a field oxide layer (not shown) is formed over a substrate 41. A shallow trench isolation (STI) process can be used to form the field oxide layer. Specifically, a pad oxide layer (not shown) and a pad nitride layer (not shown) are sequentially formed over the substrate 41 where an active region and a field region are defined. Subsequently, the pad oxide layer and the pad nitride layer are patterned. A trench for isolation is formed using the patterned pad oxide layer and the patterned pad nitride layer as a mask. An oxide layer is formed over the substrate including the trench. A planarization process, e.g., a chemical mechanical polishing (CMP) process, is performed on the oxide layer formed over the substrate so that the oxide layer fills the trench, thereby forming a field oxide layer (not shown). The field oxide layer is preferably formed using an oxide layer made by a high density plasma-chemical vapor deposition (HDP-CVD) process to easily fill the trench. Further, a wet cleaning process is performed to remove the pad nitride layer and the pad oxide layer so that a surface of the substrate 41 in the active region is exposed.

Subsequently, a sacrificial oxide layer 42 having a higher wet-etch rate than the substrate 41 and the field oxide layer (not shown) is formed over the substrate 41. The sacrificial layer 42 is made of an oxide layer having a high wet-etch rate to wet-etch the sacrificial oxide layer 42 in a subsequent etch process. Therefore, in the process for etching the sacrificial oxide layer 42, it is easy to stop the etching at the surface of the substrate 41. Thus, it is possible to uniformly adjust the depth of a recess 46 (as shown in FIGS. 4D to. 4F) to be formed in a subsequent process and to decrease loss of the field oxide layer by an anisotropic etch characteristic of the wet-etching. Furthermore, sidewalls of the sacrificial oxide layer 42 is partially removed by the anisotropic wet-etch process and thus a top corner (E) of the recess 46 is exposed to have a round shape.

Further, the sacrificial oxide layer 42 includes a low pressure tetra ethyl ortho silicate (LPTEOS) layer having a high etch rate. It is preferable that the LPTEOS layer is formed to have a thickness of approximately 50 Å to approximately 500 Å.

Then, a hard mask layer 43 is formed over the sacrificial oxide layer 42. The hard mask layer 43 has a stack structure of an amorphous carbon layer 43A and a silicon oxy-nitride (SiON) layer 43B. The SiON layer 43B is formed to have a given thickness, which can be removed in the process of forming the recess 46. Preferably, the SiON layer 43B has a thickness of approximately 100 Å to approximately 600 Å.

A photoresist pattern 45 defining a recess target region is formed over the hard mask layer 43. An anti-reflection coating (ARC) layer 44 may be formed below the photoresist pattern 45.

Referring to FIG. 4B, the hard mask layer 43 is etched using the photoresist pattern 45 as an etch mask. Specifically, the SiON layer 43B is etched using the photoresist pattern 45 as an etch mask. Hereinafter, the etched SiON layer 43B is called a SiON pattern 43B1. The amorphous carbon layer 43A is etched using the photoresist pattern 45 and the SiON pattern 43B1 as an etch barrier. When etching the amorphous carbon layer 43A, the photoresist pattern 45 is almost removed. The amorphous carbon layer 43A is etched until the sacrificial oxide layer 42 is exposed. In this etching process, it is preferable that the sacrificial oxide layer 42 remains un-etched to adjust the depth of the recess 46 later. For the sacrificial oxide layer 42 to be un-etched, the etch process is performed in a condition where the amorphous carbon layer 43A has a higher etch rate than the sacrificial oxide layer 42. This etch process is performed using one of a gas mixture of nitrogen (N₂)/oxygen (O₂)/hydrogen bromide (HBr), a gas mixture of N₂/hydrogen (H₂), and a sulfur dioxide (SO₂).

In another embodiment according to the present invention, the etch process can be performed in two steps. In the first step, a main-etch process is performed by using a main gas of N₂/O₂ and an additional gas of HBr/chlorine (Cl₂). In the second step, an over-etch process is performed by using a gas mixture of N₂/O₂/HBr. Hereinafter, the etched amorphous carbon layer 43A is called an amorphous pattern 43A1. The etched hard mask layer 43 including the SiON pattern 43B1 and the amorphous pattern 43A1 is called a hard mask pattern 43A.

Referring to FIG. 4C, a wet-cleaning process is performed by using a certain chemical. Thus, an etch residual generated during etching the hard mask layer 43 and a remaining photoresist pattern are removed while simultaneously etching the exposed sacrificial oxide layer 42. This is possible because the sacrificial oxide layer 42 is made of an oxide layer having a high wet-etch rate.

If the sacrificial oxide layer 42 is wet-etched, the sacrificial oxide layer 42 is entirely removed while the substrate 41 is scarcely lost. That is, since it is easy to stop etching the sacrificial oxide layer 42 at the surface of the substrate 41, it is possible to form the recess 46 having a constant depth in a subsequent process. Also, if the sacrificial oxide layer 42 is isotropically wet-etched, loss of the field oxide layer (not shown) can be reduced. Furthermore, if the sacrificial oxide layer 42 is isotropically wet-etched, the sidewall (D) of the sacrificial oxide layer 42 is partially lost to form a sacrificial oxide pattern 42A. The sacrificial oxide pattern 42A has a smaller width than the hard mask pattern 43A. Thus, the top corner of the recess 46 is exposed and formed in the round shape.

Further, the wet-etch process is performed by using hydrogen fluoride (HF) chemical as an example. At this time, the sacrificial oxide layer 42 may include the above-mentioned LPTEOS layer or an oxide layer having a higher wet-etch rate to the HF chemical than the LPTEOS layer. While performing the wet-etch process using the HF chemical, the LPTEOS layer having the high etch rate to the HF chemical can be completely removed and the remaining photoresist pattern can also be removed. Furthermore, it is possible to prevent the amorphous carbon pattern 43A1 from being removed. When the LPTEOS layer is etched, the loss of the sidewall can be adjusted to a range of approximately 10 Å to approximately 300 Å and the loss of the field oxide layer, e.g., a high density plasma (HDP) layer, can be adjusted to a range less than approximately 100 Å.

Referring to FIG. 4D, the exposed substrate 41 is etched to a certain depth using the SiON pattern 43B1 and the amorphous carbon pattern 43A1 as an etch barrier to form the recess 46. The SiON pattern 43B1 is removed during the etch process to form the recess 46. Hereinafter, the etched substrate 41 is called a substrate pattern 41A.

Referring to FIG. 4E, the amorphous carbon pattern 43A1 may be removed by using a photoresist remover. When the amorphous carbon pattern 43A1 is removed, the top corner E of the recess 46 is exposed and hence a beak is generated at the top corner (E).

Then, a typical cleaning process is performed to remove the residual from the process for forming the recess 46. Therefore, the sacrificial oxide pattern 42A remains over the substrate pattern 41A.

Referring to FIG. 4F, a light etch treatment (LET) process is performed on the resultant structure to round off the top corner E. The LET process is preferably performed in a down stream etch apparatus by using a gas mixture of CF₄ and O₂. Furthermore, the LET process can cure a surface of the substrate pattern 41A damaged during forming the recess 46 and remove a horn generated on a borderline between a field region and an active region after the recess 46 is etched.

In accordance with the present invention, the sacrificial oxide layer is made of an oxide layer having a higher wet-etch rate than a substrate and a field oxide layer and the oxide layer is wet-etched in a subsequent etch process. As a result, it is possible to secure a uniformity of a recess depth, decrease loss of the field oxide layer, and prevent a beak generation by rounding the top corner of the recess pattern, improving device performance.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor device, the method comprising:
providing a substrate;
forming a sacrificial oxide layer over the substrate, the sacrificial layer having a higher etch rate than the substrate;
forming a hard mask pattern over the sacrificial oxide layer;
wet-etching the sacrificial oxide layer using the hard mask pattern as an etch barrier; and
forming a recess by etching an exposed substrate using the hard mask pattern as an etch barrier.

2. The method of claim 1, further comprising rounding a top corner of the recess after forming the recess.

3. The method of claim 1, wherein the sacrificial oxide layer includes a low pressure tetra ethyl ortho silicate (LPTEOS) layer.

4. The method of claim 3, wherein the LPTEOS layer has a thickness of approximately 50 Å to approximately 500 Å.

5. The method of claim 1, wherein the hard mask pattern has a stack structure of an amorphous carbon layer and a silicon nitride (SiON) layer.

6. The method of claim 5, wherein the SiON layer has a thickness of approximately 100 Å to approximately 600 Å.

7. The method of claim 1, wherein forming the hard mask pattern comprises:
forming an amorphous carbon layer and a silicon nitride (SiON) layer over the oxide sacrificial layer;
forming a photoresist pattern to define a recess target region over the SiON layer;
etching the SiON layer using the photoresist pattern as an etch barrier; and
etching the amorphous carbon layer using the photoresist pattern and the etched SiON layer as an etch barrier while the sacrificial oxide layer being un-etched.

8. The method of claim 7, wherein the amorphous carbon layer has a higher etch rate than the sacrificial oxide layer.

9. The method of claim 8, wherein etching the amorphous carbon layer is performed by using one of a gas mixture of nitrogen (N₂)/oxygen (O₂)/hydrogen bromide (HBr), a gas mixture of N₂/hydrogen (H₂), a gas mixture of N₂/H₂/methane (CH₄), and a sulfur dioxide (SO₂) gas.

10. The method of claim 8, wherein etching the hard mask amorphous carbon layer comprises:
performing a main-etch process by using a gas mixture of N₂/O₂ as a main gas added with a gas mixture of HBr/chlorine (Cl₂); and
performing an over-etch process by using a gas mixture of N₂/O₂/HBr.

11. The method of claim 1, wherein the sacrificial oxide layer is wet-etched by using a hydrogen fluoride (HF) chemical.

12. The method of claim 11, wherein etching the sacrificial oxide layer is performed to lose its sidewall approximately 10 Å to approximately 300 Å.

13. The method of claim 2, wherein rounding the top corner of the recess is performed by a light etch treatment (LET) process.

14. The method of claim 13, wherein the LET process is performed in a down stream etch apparatus by using a gas mixture of tetrafluoromethane (CF₄)/O₂.

15. The method of claim 1, further comprising forming an isolation layer over the substrate before forming the sacrificial oxide layer.

16. The method of claim 15, wherein forming the isolation layer is performed by a shallow trench isolation (STI) process and a pad oxide layer and a nitride layer used for the STI process are removed by a wet-cleaning process.

17. The method of claim 1, wherein the substrate includes a field oxide layer for an isolation.

18. The method of claim 17, wherein the sacrificial oxide layer has a higher etch rate than the field oxide layer.

19. The method of claim 18, wherein the field oxide layer is formed by a high density plasma-chemical vapor deposition (HDP-CVD) process and the sacrificial oxide layer includes a low pressure tetra ethyl ortho silicate (LPTEOS) layer.
